(19) United States
(12) Patent Application Publication
(10) Pub. No.: US 2015/0187922 A1
(43) Pub. Date: Jul. 2, 2015

(54) POWER SEMICONDUCTOR DEVICE

(71) Applicant: SAMSUNG ELECTRO-MECHANICS CO., LTD., Suwon-Si (KR)

(72) Inventors: In Hyuk SONG, Suwon-Si (KR); Ji Yeon Oh, Suwon-Si (KR); Ji Hye Kim, Suwon-Si (KR); Sun Jae Yoon, Suwon-Si (KR); Jae Hoon Park, Suwon-Si (KR)

(73) Assignee: SAMSUNG ELECTRO-MECHANICS CO., LTD., Suwon-Si (KR)

(21) Appl. No.: 14/274,249

(22) Filed: May 9, 2014

(30) Foreign Application Priority Data
Dec. 27, 2013 (KR) 10-2013-0165241

(51) Int. Cl. H01L 29/739; H01L 29/10

(52) U.S. Cl. CPC H01L 29/7397; H01L 29/1004

(57) ABSTRACT

A power semiconductor device may include: a first conductivity-type drift region in which a plurality of trench gates each including a gate insulating layer disposed on a surface thereof and a conductive material filling the interior thereof are disposed; a second conductivity-type body region disposed on an inner side of an upper portion of the drift region and disposed to be in contact with the trench gate; a first conductivity-type emitter region disposed on an inner side of an upper portion of the body region and disposed to be in contact with the trench gate; and a hole accumulation region disposed in the drift region, disposed below the body region, and disposed between the trench gates.

### CROSS-REFERENCE TO RELATED APPLICATION

This application claims the benefit of Korean Patent Application No. 10-2013-0165241 filed on Dec. 27, 2013, with the Korean Intellectual Property Office, the disclosure of which is incorporated herein by reference.

### BACKGROUND

The present disclosure relates to a power semiconductor device

An insulated-gate bipolar transistor (IGBT) is a transistor with a gate manufactured by using a metal-oxide semiconductor (MOS) structure and forming a p-type collector layer on a rear surface thereof having bipolarity.

Since the development of conventional power Metal-Oxide Semiconductor Field Emission Transistors (MOSFET), such MOSFETs have been used in fields in which fast switching characteristics are required.

However, due to inherent structural limitations of MOSFETs, bipolar transistors, thyristors, gate turn-off thyristors (GTO), and the like, have been used in fields in which high voltage are required.

IGBTs, featuring low forward loss and fast switching speeds, tend to extendedly applied to applications in various fields for which existing thyristors, bipolar transistors, MOSFETs, and the like are unsuitable.

As for an operating principle of an IGBT, in the case that an IGBT device is turned on and a voltage higher than that of a cathode is applied to an anode, while a voltage higher than a threshold value of the device is applied to a gate electrode, a polarity of a surface of a p-type body region positioned in a lower end portion of the gate electrode is reversed to form an n-type channel.

An electron current injected into a drift region through the n-type channel induces injection of a hole current from a p-type collector layer having a high concentration positioned in a lower portion of the IGBT device, such as a base current of a bipolar transistor.

The injection of the minority carrier having a high concentration increases conductivity in the drift region by tens to hundreds of times (an order of magnitude of one or two), causing conductivity modulation.

Unlike a MOSFET, a resistance component in the drift region may be reduced in size to be significantly low due to the conductivity modulation, and thus, extremely high voltages may be applied to IGBT devices.

A current flowing to a cathode may be divided into an electron current, flowing through a channel, and a hole current, flowing through a junction between a p-type body and an n-type drift region.

An IGBT may have a PNP structure between an anode and a cathode in terms of a substrate structure, so unlike a MOSFET, a diode may not be installed, and thus, a separate diode may need to be connected to an IGBT through an inverse-parallel connection.

The development of IGBTs aims at maintaining a blocking voltage, reducing conduction loss, and improving switching characteristics.

In the development of techniques of the foregoing IGBT, research into an IGBT further including a hole accumulation layer to reduce conduction loss has been actively conducted.

With the presence of a hole accumulation layer, conduction modulation may be maximized due to accumulated holes to reduce conduction loss.

In this case, however, since a hole accumulation layer is formed by injecting an n-type impurity having a high concentration, it is difficult to extend a depletion layer in a blocking mode, increasing a field effect to reduce a blocking voltage.

Thus, there is a limitation in increasing an impurity concentration in the hole accumulation layer, making it difficult to improve conduction loss.

### SUMMARY

An aspect of the present disclosure may provide a power semiconductor device in which conduction loss is lowered and a blocking voltage is increased.

According to an aspect of the present disclosure, a power semiconductor device may include: a first conductivity-type drift region in which a plurality of trench gates each including a gate insulating layer disposed on a surface thereof and a conductive material filling the interior thereof are disposed; a second conductivity-type body region disposed on an inner side of an upper portion of the drift region and disposed to be in contact with the trench gate; a first conductivity-type emitter region disposed on an inner side of an upper portion of the body region and disposed to be in contact with the trench gate; and a hole accumulation region disposed in the drift region, disposed below the body region, and disposed between the trench gates, wherein when a portion corresponding to the body region of the trench gate is a first gate part, a portion corresponding to the hole accumulation region is a second gate part, and a portion corresponding to the drift region is a third gate part based on a height of the trench gate, a thickness of the gate insulating layer corresponding to the second gate part is different from that of the gate insulating layer corresponding to the third gate part.

The thickness of the gate insulating layer corresponding to the second gate part may be smaller than that of the gate insulating layer corresponding to the third gate part.

The thickness of the gate insulating layer corresponding to the second gate part may be smaller than that of the gate insulating layer corresponding to the first gate part.

The power semiconductor device may further include: a buffer region disposed below the drift region and having an impurity concentration higher than that of the drift region.

The impurity concentration in the hole accumulation region may be reduced as the hole accumulation region becomes distant from the trench gate.

According to another aspect of the present disclosure, a power semiconductor device may include: a first conductivity-type drift region; a first conductivity-type hole accumulation region disposed above the drift region and having an impurity concentration higher than that of the drift region; a second conductivity-type body region disposed above the hole accumulation region; a first conductivity-type emitter region disposed on an inner side of an upper portion of the body region; and a trench gate disposed to penetrate from the emitter region to at least a portion of the hole accumulation region, and including a gate insulating layer disposed on a surface thereof and a conductive material filling the interior thereof, wherein when a portion of the trench gate corresponding to the body region is a first gate part and a portion thereof corresponding to the hole accumulation region is a second gate part based on the trench gate, a thickness of the gate insulating layer corresponding to the second gate part is different from that of the gate insulating layer corresponding to the first gate part.

The trench gate may be disposed to penetrate through into a portion in which the drift region and the hole accumulation region are contiguous.

A thickness of the gate insulating layer of the second gate part may be smaller than that of the gate insulating layer of the first gate part.

The impurity concentration in the hole accumulation region may be reduced as the hole accumulation region becomes distant from the trench gate.

The power semiconductor device may further include a buffer region disposed below the drift region.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view schematically illustrating a power semiconductor device according to an exemplary embodiment of the present disclosure; and

FIG. 2 is a cross-sectional view schematically illustrating a power semiconductor device according to another exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

A power switch may be implemented by any one of a power metal-oxide semiconductor field emission transistor (MOSFET), an insulated-gate bipolar transistor (IGBT), various types of thyristor, or the like. Most new techniques disclosed herein will be described based on IGBTs. However, various exemplary embodiments disclosed herein are not limited to IGBTs and may be applied to any type of power switch technique, including power MOSFETs and various types of thyristors, besides IGBTs. In addition, various exemplary embodiments of the present disclosure are described to include particular p-type and n-type regions. However, obviously, the exemplary embodiments described herein may also be applied to devices including regions having opposite conductivity types in the same manner.

Also, as used herein, p-type and n-type may be defined as a first conductivity-type or a second conductivity-type. Meanwhile, first and second conductivity-types refer to different conductivity-types.

Also, in general, positive (+) refers to an element doped at a high concentration and negative (−) refers to an element state doped at a low concentration.

Hereinafter, for clarification, a first conductivity-type will be referred to as an n-type, while a second conductivity-type will be referred to as a p-type, but the present disclosure is not limited thereto.

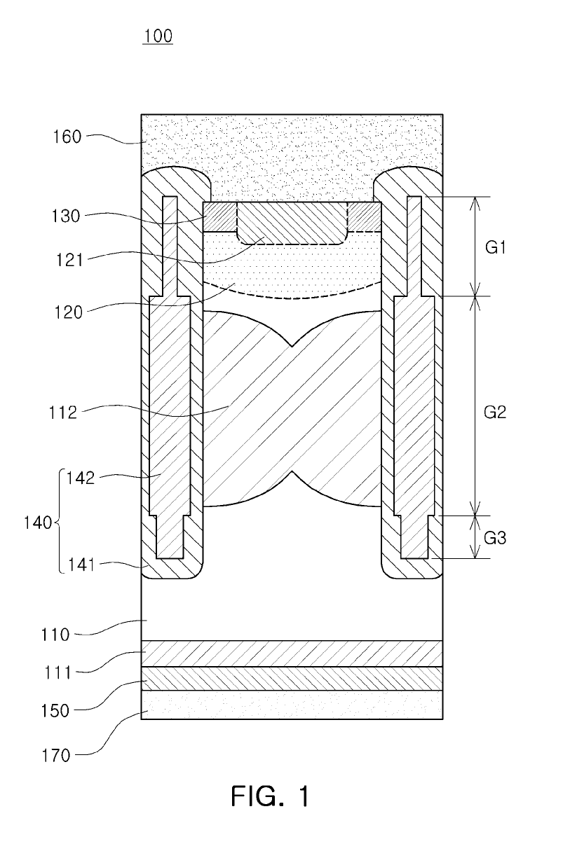

FIG. 1 is a cross-sectional view schematically illustrating a power semiconductor device 100 according to an exemplary embodiment of the present disclosure.

A structure of the power semiconductor device 100 according to an exemplary embodiment of the present disclosure will be described with reference to FIG. 1. The power semiconductor device 100 according to an exemplary embodiment of the present disclosure may include a collector region 150, a drift region 110, a body region 120, and an emitter region 130.

The drift region 110 may be formed by injecting an n-type impurity with low concentration.

Thus, in order to maintain a blocking voltage of the device, the drift region 110 has a relatively large thickness.

The drift region 110 may include a buffer region 111 in a low portion thereof.

The buffer region 111 may be formed by injecting an n-type impurity into a rear surface of the drift region 110.

The buffer region 111 may serve to hinder expansion of a depletion region of the device, helping to maintain a blocking voltage of the device.

Thus, in the case that the buffer region 111 is formed, the drift region 110 may be formed to be thinner, reducing the size of the power semiconductor device.

The body region 120 may be formed by injecting a p-type impurity into an upper surface of the drift region 110.

The body region 120 may have p-type conductivity, forming a p-n junction with the drift region 110.

The body region 120 may be formed to have a stripe shape above the drift region 110.

The emitter region 130 may be formed by injecting an n-type impurity having a high concentration into the upper surface of the body region 120.

A trench gate 140 may be formed to penetrate from the emitter region 130, through the body region 120, to the drift region 110.

Namely, the trench gate 140 may be formed to penetrate from the emitter region 130 into a portion of the drift region 110.

The trench gate 140 may be formed extendedly in one direction and may be arranged at a predetermined interval in a direction perpendicular to the direction in which the trench gates 140 are formed extendedly.

A gate insulating layer 141 may be formed in portions of the trench gate 140 in contact with the drift region 110, the body region 120, and the emitter region 130.

The gate insulating layer 141 may be formed of silicon oxide (SiO₂), but the present disclosure is not limited thereto.

The gate insulating layer 141 may be formed of silicon oxide (SiO₂), but the present disclosure is not limited thereto.

The interior of the trench gate 140 may be filled with a conductive material 142.

The conductive material 142 may be polysilicon (Poly-Si) or a metal, but the present disclosure is not limited thereto.

The conductive material 142 is electrically connected to a gate electrode (not shown) to control an operation of the power semiconductor device 100 according to the exemplary embodiment of the present disclosure.

In the case that a positive (+) voltage is applied to the conductive material 142, a channel C is formed in the body region 120.

In detail, in the case that a positive (+) voltage is applied to the conductive material 142, electrons present in the body region 120 are attracted toward the trench gate 140, so electrons gathering at the trench gate 140 form a channel.

Namely, the trench gate 140 attracts electrons to form a channel in a depletion region with no carriers due to electron-hole recombination occurring at a p-n junction, allowing a current to flow.

The collector region 150 may be formed by injecting a p-type impurity into a lower surface of the drift region 110 or a lower surface of the buffer region 111.

In a case in which the power semiconductor device is an insulated-gate bipolar transistor (IGBT), the collector region 150 may provide holes to the power semiconductor device 100.

The injection of holes, minority carriers, having a high concentration causes conductivity modulation that conductivity is increased by tens to hundreds of times in the drift region 110.

An emitter metal layer 160 may be formed on the emitter region 130 and an exposed upper surface of the body region 120, and a collector metal layer 170 may be formed on a lower surface of the collector region 150.

The power semiconductor device 100 according to an exemplary embodiment of the present disclosure may further include a hole migration region 121 in order to prevent occurrence of latch-up.

The hole migration region 121 may be formed by injecting a p-type impurity having high concentration into an upper surface of the body region 120.

Since the home migration region 121 is formed, a hole current does not flow to the emitter region 130, preventing occurrence of latch-up and increasing reliability of the power semiconductor device 100.

The power semiconductor device 100 according to an exemplary embodiment of the present disclosure may include a hole accumulation region 112 in order to maximize conductivity modulation.

The hole accumulation region 112 may be formed by injecting an n-type impurity.

The hole accumulation region 112 may be formed to have an impurity concentration higher than that of the drift region 110.

Since the hole accumulation region 112 has an n+-type impurity concentration, holes may be accumulated due to the hole accumulation region 112.

Since holes are accumulated, conductivity modulation in the power semiconductor device 100 may be maximized, and thus, conduction loss may be reduced.

The hole accumulation region 112 may be formed by injecting an n-type impurity with high energy, but the present disclosure is not limited thereto.

For example, the hole accumulation region 112 may be formed by etching the trench gate 140 to a depth by which the hole accumulation region 112 is to be formed, to prepare a preliminary trench and injecting an n-type impurity having a high concentration, during the process of forming the trench gate 140.

After the n-type impurity is injected, the preliminary trench may be etched to a depth to which the region of the trench gate 140 is to be formed, and heat-treated to form the hole accumulation region 112.

As described above, in the case in which the hoe accumulation region 112 is formed during the process of forming the trench gate 140, an impurity concentration in the hole accumulation region 112 may be reduced in a direction of the hole accumulation region 112 away from the trench gate 140.

Thus, the impurity concentration in the hole accumulation region 112 is the lowest in a central portion between the trench gates 140.

The power semiconductor device 100 may have a parasitic thyristor having a PNPN structure from a lower portion thereof.

Latch-up refers to a state in which a parasitic thyristor operates and the power semiconductor device is not controlled by a gate any longer.

Once the parasitic thyristor operates, the IGBT may not be subjected to be controlled by a gate any longer and a huge amount of current flows to an anode and a cathode to generate a high level of heat to burn the device.

The phenomenon that a parasitic thyristor is increased is called latch-up.

The principle of generating latch-up will be described in detail. When a power semiconductor device operates, an electron current flows along a channel and a hole current moves across the junction of the body region 120 to flow to the emitter electrode 160.

Since the electron current is injected into the drift region 110 below the trench gate 140 along the channel to increase conductivity of the region, most hole current is injected from the body region 120 below the channel and flow to the emitter metal layer 160 through a lower portion of the emitter region 130.

In the case that the hole current is increased and a voltage drop in a lower portion of the emitter region 130 is greater than a potential barrier of an interface between the emitter region 130 and the body region 120, making the junction forward biased, electrons are injected from the emitter region 130 to the body region 120 and a parasitic NPN thyristor including the n-type emitter region 130, the p-type body region 120, and the n-type drift region 110 operates.

Thus, in the case in which the structure for increasing accumulation of holes in the power semiconductor device is provided, although conduction loss is reduced, a hole current may be increased to increase the possibility of generating latch-up.

However, in the power semiconductor device 100 according to the present exemplary embodiment, since the impurity concentration in the hole accumulation region 112 is reduced as the hole accumulation region 112 becomes distant from the trench gate 140, and thus, a hole current may flow to a central portion between adjacent trench gates 140.

Thus, since the hole current does not overpass to the emitter region 130, preventing occurrence of latch-up.

Also, since the hole accumulation region 112 below the channel in which an electron current flows has an n-type impurity having a high concentration, and thus, conductivity modulation is maximized to reduce conduction loss.

Also, in the case in which the hole accumulation region 112 is formed, the hole accumulation region 112 may serve to hinder a depletion region from expanding in a blocking mode of the power semiconductor device 100, due to the high an n-type impurity concentration therein.

Thus, in the case of the related art, a blocking voltage of the power semiconductor device is reduced due to the hole accumulation region 112.

In the power semiconductor device 100 according to the present exemplary embodiment, the gate insulating layer 141 of the trench gate 140 may be different depending on a height of the trench gate 140.

For example, depending on a height of the trench gate 140, a portion of the trench gate 140 corresponding to the body region 120 and the emitter region 130 may be defined as a first gate part G1, a portion thereof corresponding to the hole accumulation region 112 may be defined as a second gate part G2, and a portion thereof corresponding to the drift region 110 may be defined as a third gate part G3.

The first gate part G1 refers to a part positioned above the second gate part G2 formed to correspond to the hole accumulation region 112, and the third gate part G3 refers to a part positioned below the second gate part G2.

Here, thicknesses of the gate insulating layer 141 corresponding to the first gate part G1, the second gate part G2, and the third gate part G3 may differ.

Since the hole accumulation region 112 serves to hinder a depletion region from expanding in the blocking mode of the power semiconductor device 100, there is a limitation in increasing an impurity concentration in the hole accumulation region 112.

However, in the power semiconductor device 100 according to the present exemplary embodiment, by adjusting the thicknesses of the gate insulating layer 141 corresponding to the first gate part G1, the second gate part G2, and the third gate part G3 to be different, a blocking voltage of the power semiconductor device 100 may be enhanced.

For example, the gate insulting layer 141 corresponding to the second gate part G2 may be formed to be thinner than those of the other gate parts G1 and G3.

Here, by forming the gate insulting layer 141 corresponding to the second gate part G2 to be thinner than those of the other gate parts G1 and G3, a depletion region of the hole accumulation region 112 may rapidly expand in the blocking mode.

Namely, even when the hole accumulation region 112 is formed, the depletion region may rapidly expand in the hole accumulation region 112 to prevent a reduction in a blocking voltage.

Thus, conduction loss may be reduced by increasing the impurity concentration in the hole accumulation region 112, while maintaining a blocking voltage.

Also, in general, a blocking voltage is concentrated on a lower end portion of the trench gate 140.

An insulating blocking voltage is generated in the third gate part G3, and by adjusting the third gate part G3 to have a thickness greater than that of the second gate part G2, a reduction in the insulating blocking voltage may be prevented.

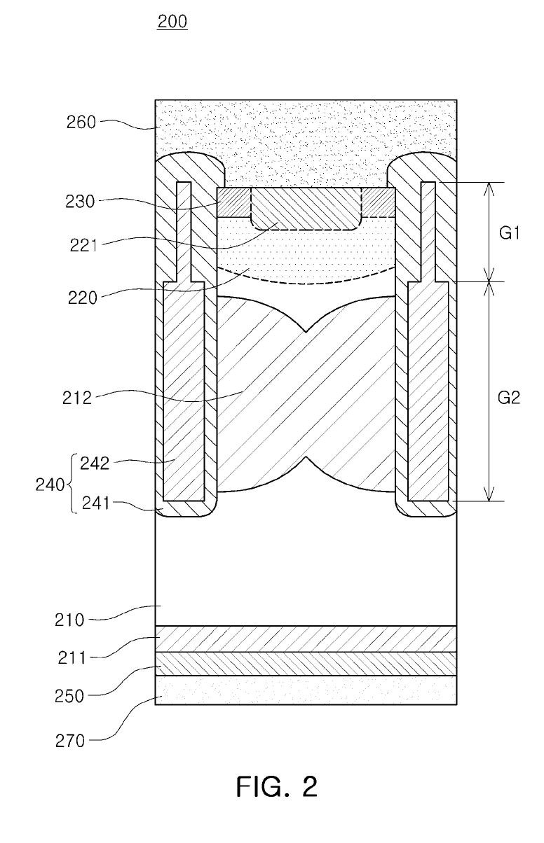

FIG. 2 is a cross-sectional view schematically illustrating a power semiconductor device 200 according to another exemplary embodiment of the present disclosure.

Hereinafter, descriptions of components the same as those of the power semiconductor device 100 according to an exemplary embodiment of the present disclosure will be omitted.

Referring to FIG. 2, a trench gate 240 may be formed to penetrate through to a region in which a drift region 210 and a hole accumulation region 212 are contiguous.

In general, a lower end portion of the trench gate 240 is a portion on which an electric field is concentrated to reduce a blocking voltage and acts as gate-collector capacitance (Cgc).

Thus, by forming the trench gate 240 to penetrate through to the portion in which the drift region 210 and the hole accumulation region 212 are contiguous, a reduction in a blocking voltage may be prevented and generation of Cgc may be basically reduced.

In the power semiconductor device 200 according to another exemplary embodiment of the present disclosure, since the trench gate 240 does not penetrate through into a portion of the drift region 210, a configuration corresponding to the third gate part G3 of the power semiconductor device 200 according to the former exemplary embodiment is not included.

However, in the power semiconductor device 200 according to another exemplary embodiment of the present disclosure, in order to reduce a reduction in an insulating blocking voltage, a thickness of an insulating layer 241 at the lower end portion of the trench gate 240 may be greater than that of the gate insulating layer 241 of the second gate part G2.

As set forth above, in the power semiconductor device according to exemplary embodiments of the present disclosure, since a gate insulating layer of a trench gate in contact with a portion in which a hole accumulation region is formed is formed to have a reduced thickness, a depletion layer of a hole accumulation region may rapidly expand in a blocking mode, and thus, a blocking voltage may be increased.

Since the blocking voltage is enhanced, conductivity modulation may be maximized by further increasing an n-type impurity concentration in the hole accumulation region, thus reducing conduction loss.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device comprising:
a first conductivity-type drift region in which a plurality of trench gates each including a gate insulating layer disposed on a surface thereof and a conductive material filling the interior thereof are disposed;
a second conductivity-type body region disposed on an inner side of an upper portion of the drift region and disposed to be in contact with the trench gate;
a first conductivity-type emitter region disposed on an inner side of an upper portion of the body region and disposed to be in contact with the trench gate; and
a hole accumulation region disposed in the drift region, disposed below the body region, and disposed between the trench gates,
wherein when a portion corresponding to the body region of the trench gate is a first gate part, a portion corresponding to the hole accumulation region is a second gate part, and a portion corresponding to the drift region is a third gate part based on a height of the trench gate, a thickness of the gate insulating layer corresponding to the second gate part is different from that of the gate insulating layer corresponding to the third gate part.

2. The power semiconductor device of claim 1, wherein the thickness of the gate insulating layer corresponding to the second gate part is smaller than that of the gate insulating layer corresponding to the third gate part.

3. The power semiconductor device of claim 1, wherein the thickness of the gate insulating layer corresponding to the second gate part is smaller than that of the gate insulating layer corresponding to the first gate part.

4. The power semiconductor device of claim 1, further comprising a buffer region disposed below the drift region and having an impurity concentration higher than that of the drift region.

5. The power semiconductor device of claim 1, wherein the impurity concentration in the hole accumulation region is reduced as the hole accumulation region becomes distant from the trench gate.

6. A power semiconductor device comprising:
a first conductivity-type drift region;
a first conductivity-type hole accumulation region disposed above the drift region and having an impurity concentration higher than that of the drift region;
a second conductivity-type body region disposed above the hole accumulation region;
a first conductivity-type emitter region disposed on an inner side of an upper portion of the body region; and
a trench gate disposed to penetrate from the emitter region and penetrating to at least a portion of the hole accumulation region, and including a gate insulating layer disposed on a surface thereof and a conductive material filling the interior thereof,
wherein when a portion of the trench gate corresponding to the body region is a first gate part and a portion thereof corresponding to the hole accumulation region is a second gate part based on the trench gate, a thickness of the gate insulating layer corresponding to the second gate part is different from that of the gate insulating layer corresponding to the first gate part.

7. The power semiconductor device of claim 6, wherein the trench gate is disposed to penetrate through into a portion in which the drift region and the hole accumulation region are contiguous.

8. The power semiconductor device of claim 6, wherein a thickness of the gate insulating layer of the second gate part is smaller than that of the gate insulating layer of the first gate part.

9. The power semiconductor device of claim 6, wherein the impurity concentration in the hole accumulation region is reduced as the hole accumulation region becomes distant from the trench gate.

10. The power semiconductor device of claim 6, further comprising a buffer region disposed below the drift region.
